(19) United States
(12) Patent Application Publication
(10) Pub. No.: US 2025/0194788 A1
(43) Pub. Date: Jun. 19, 2025

(54) APPARATUS FOR CLEANING BRUSHES

(71) Applicant: SAMSUNG ELECTRONICS CO., LTD., Suwon-si (KR)

(72) Inventors: Jubong Lee, Suwon-si (KR); Hyuntae Lee, Suwon-si (KR); Ahra Jeon, Suwon-si (KR); Sungyong Park, Suwon-si (KR); Jaemin Jung, Suwon-si (KR); Hoseop Choi, Suwon-si (KR)

(21) Appl. No.: 18/671,672

(22) Filed: May 22, 2024

(30) Foreign Application Priority Data
Dec. 15, 2023 (KR) 10-2023-0183139

(51) Int. Cl. A46B 17/06; B08B 1/52; B08B 1/54; B08B 3/02; B08B 7/02

(52) U.S. Cl. CPC A46B 17/06; B08B 1/52; B08B 1/54; B08B 3/02; B08B 7/028; A46B 2200/3073

(57) ABSTRACT

An apparatus for cleaning brushes may include a scrubbing jig and at least two scrubbing surfaces. The scrubbing jig may be configured to scrub at least two brushes used in cleaning a wafer. The at least two scrubbing surfaces may be provided to the scrubbing jig to make contact with the at least two brushes. Accordingly, a contamination of a wafer by contaminants in the brushes may be suppressed in a following cleaning process.

### CROSS-REFERENCE TO RELATED APPLICATION

This application claims priority to Korean Patent Application No. 10-2023-0183139, filed in the Korean Intellectual Property Office (KIPO) on Dec. 15, 2023, the contents of which are incorporated herein by reference in their entirety.

### BACKGROUND

Generally, after performing a chemical mechanical polishing (CMP) process on a wafer, a cleaning process may be performed to remove contaminants from the wafer. The cleaning process may be performed using brushes. The brushes used in a previous cleaning process may include the contaminants so that it may be required to clean the brushes using a cleaning apparatus before using the brushes in a following cleaning process. Although the cleaning apparatus may clean only one brush among the plurality of the brushes, it may be desired to clean the plurality of the brushes.

### SUMMARY

In general, in some aspects, the present disclosure is directed to an apparatus for cleaning brushes capable of improved cleaning efficiency.

According to some aspect, the present disclosure is directed to an apparatus for cleaning brushes. The apparatus may include a scrubbing jig and at least two scrubbing surfaces. The scrubbing jig may be configured to scrub at least two brushes used in cleaning a wafer. The at least two scrubbing surfaces may be provided to the scrubbing jig to make contact with the at least two brushes.

According to some aspects, the present disclosure is directed to an apparatus for cleaning brushes. The apparatus may include a scrubbing jig, an upper cleaning nozzle and a lower cleaning nozzle. The scrubbing jig may be rotatably arranged between an upper brush and a lower brush used in cleaning a wafer with respect to a vertical axis to simultaneously scrub the upper brush and the lower brush. The upper cleaning nozzle may inject a cleaning agent to the upper brush and/or an upper surface of the scrubbing jig. The lower cleaning nozzle may inject the cleaning agent to the lower brush and/or a lower surface of the scrubbing jig.

According to some aspects, the present disclosure is directed to an apparatus for cleaning brushes. The apparatus may include a scrubbing jig, an upper cleaning nozzle, a lower cleaning nozzle, an upper ultrasonic wave nozzle, a lower ultrasonic wave nozzle, an imager and a controller. The scrubbing jig may be rotatably arranged between an upper brush and a lower brush used in cleaning a wafer with respect to a vertical axis to simultaneously scrub the upper brush and the lower brush. The upper cleaning nozzle may inject a cleaning agent to the upper brush and/or the upper surface of the scrubbing jig. The lower cleaning nozzle may inject the cleaning agent to the lower brush and/or a lower surface of the scrubbing jig. The upper ultrasonic wave nozzle may apply an ultrasonic wave to the upper brush and/or the upper surface of the scrubbing jig. The lower ultrasonic wave nozzle may apply an ultrasonic wave to the lower brush and/or the lower surface of the scrubbing jig. The imager may photograph the upper brush and the lower brush to obtain images of the upper brush and the lower brush. The controller may detect contamination information of the upper brush and the lower brush. The controller may control the scrubbing jig, the upper cleaning nozzle, the lower cleaning nozzle, the upper ultrasonic wave nozzle and the lower ultrasonic wave nozzle based on the contamination information.

According to some aspects, the present disclosure is directed to an apparatus for cleaning brushes that includes at least two scrubbing surfaces of a scrubbing jig may simultaneously scrub an upper brush and a lower brush to reduce a time for cleaning the upper brush and the lower brush. Further, a cleaning nozzle may inject cleaning agent to the brushes and the scrubbing jig and an ultrasonic wave nozzle may apply an ultrasonic wave to the brushes and the scrubbing jig to improve cleaning efficiency of the brushes. Furthermore, a controller may control the scrubbing jig, the cleaning nozzle, and the ultrasonic nozzle based on the contamination information to optimally clean the brushes. As a result, a contamination of a wafer by contaminants in the brushes may be suppressed in a following cleaning process.

### BRIEF DESCRIPTION OF THE DRAWINGS

Example implementations will be more clearly understood from the following detailed description, taken in conjunction with the accompanying drawings.

FIG. 1 is a perspective view illustrating an example of an apparatus for cleaning brushes according to some implementations.

FIG. 2 is a perspective view illustrating an example of an upper structure of a scrubbing jig in the apparatus in FIG. 1 according to some implementations.

FIG. 3 is a perspective view illustrating an example of a lower structure of the scrubbing jig in FIG. 2 according to some implementations.

FIG. 4 is a perspective view illustrating an example of an operation of an upper cleaning nozzle of the apparatus in FIG. 1 according to some implementations.

FIG. 5 is a perspective view illustrating an example of an operation of a lower cleaning nozzle of the apparatus in FIG. 1 according to some implementations.

FIG. 6 is a perspective view illustrating an example of an operation of an upper ultrasonic wave nozzle of the apparatus in FIG. 1 according to some implementations.

FIG. 7 is a perspective view illustrating an example of an operation of a lower ultrasonic wave nozzle of the apparatus in FIG. 1 according to some implementations.

FIG. 8 is a perspective view illustrating an example of an operation of a controller of the apparatus in FIG. 1 according to some implementations.

FIGS. 9 to 12 are views illustrating examples of operations of a cleaning nozzle and an ultrasonic wave nozzle of the apparatus in FIG. 1 according to some implementations.

### DETAILED DESCRIPTION

Hereinafter, example implementations will be explained in detail with reference to the accompanying drawings.

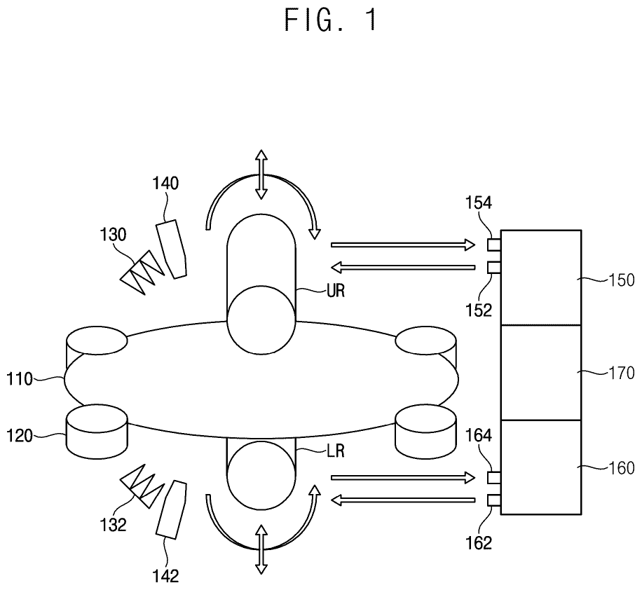

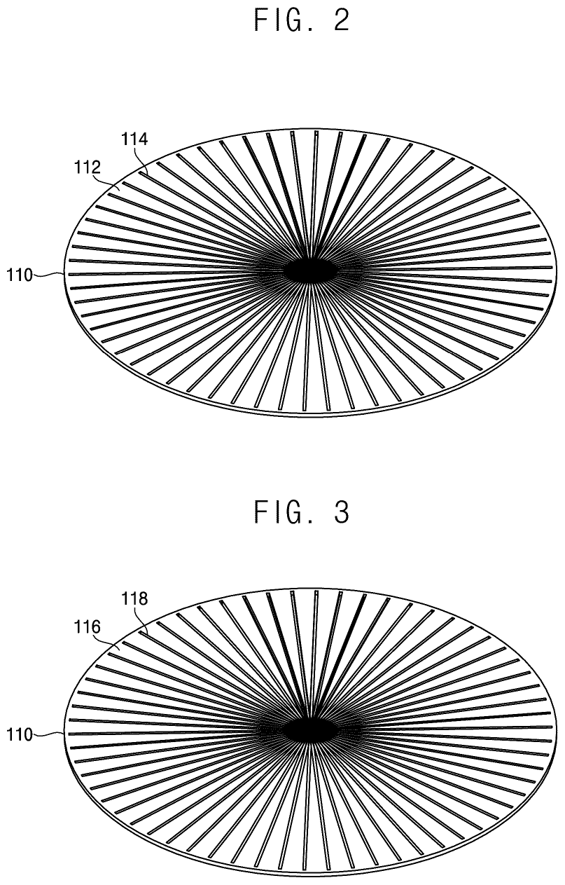

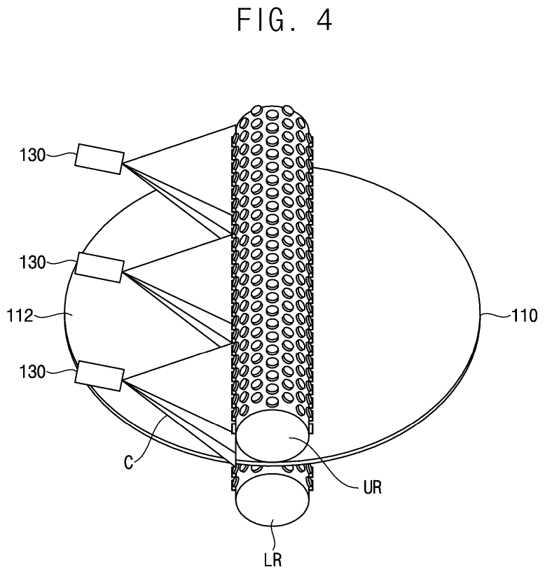

FIG. 1 is a perspective view illustrating an example of an apparatus for cleaning brushes according to some implementations, FIG. 2 is a perspective view illustrating an example of an upper structure of a scrubbing jig in the apparatus in FIG. 1 according to some implementations, and FIG. 3 is a perspective view illustrating an example of a lower structure of the scrubbing jig in FIG. 2 according to some implementations.

In FIGS. 1 to 3, an apparatus for cleaning brushes may simultaneously clean the at least two brushes used for cleaning a wafer on which a chemical mechanical polishing (CMP) process may be performed. In some implementations, the apparatus may simultaneously an upper brush UB and a lower brush LB, but not limited thereto.

The apparatus may include a scrubbing jig 110, a plurality of guide rollers 120, at least one upper cleaning nozzle 130, at least one lower cleaning nozzle 132, at least one upper ultrasonic wave nozzle 140, at least one lower ultrasonic wave nozzle 142, an upper imager 150, a lower imager 160 and a controller 170.

The scrubbing jig 110 may be interposed between the upper brush UB and the lower brush LB to simultaneously scrub the upper brush UB and the lower brush LB. That is, the upper brush UB may be scrubbed by an upper surface 112 of the scrubbing jig 110. Accordingly, the upper surface 112 of the scrubbing jig 110 may correspond to an upper scrubbing surface. The lower brush LB may be scrubbed by a lower surface 116 of the scrubbing jig 110. Accordingly, the lower surface 116 of the scrubbing jig 110 may correspond to a lower scrubbing surface.

In some implementations, the scrubbing jig 110 may have a circular plate shape, but not limited thereto. Further, the scrubbing jig 110 may include a material suitable for scrubbing the upper brush UB and the lower brush LB having PVA. In order to reinforce strength of the upper surface 112 and the lower surface 116 of the scrubbing jig 110, a reinforcing layer may be formed on the upper surface 112 and the lower surface 116 of the scrubbing jig 110.

Further, a plurality of upper scrubbing grooves 114 may be formed at the upper surface 112 of the scrubbing jig 110. The upper scrubbing grooves 114 may be radially extended from a center point of the scrubbing jig 110, but not limited thereto. A plurality of lower scrubbing grooves 118 may be formed at the lower surface 116 of the scrubbing jig 110. The lower scrubbing grooves 118 may be radially extended from the center point of the scrubbing jig 110, but not limited thereto.

The scrubbing jig 110 may be rotated with respect to a vertical axis. Accordingly, an actuator may provide the scrubbing jig 110 with a rotary force with respect to the vertical axis. The guide rollers 120 may be configured to rotatably support an edge portion of the scrubbing jig 110. In some implementations, the guide rollers 120 may be spaced apart from each other by a uniform gap.

The upper brush UB and the lower brush LB may be rotated with respect to a horizontal axis. Accordingly, the upper brush UB rotated with respect to the horizontal axis may make rotational contact with the upper surface 112 of the scrubbing jig 110 rotated with respect to the vertical axis. The lower brush LB rotated with respect to the horizontal axis may make rotational contact with the lower surface 116 of the scrubbing jig 110 rotated with respect to the vertical axis.

The upper cleaning nozzle 130 may be slantly arranged over the scrubbing jig 110. Further, the upper cleaning nozzle 130 may be positioned at one side of the upper brush UB. The upper cleaning nozzle 130 may selectively inject a cleaning agent C to the upper surface 112 of the scrubbing jig 110 and/or the upper brush UB. The cleaning agent C may include a material suitable for removing byproducts generated in the CMP process. For example, the cleaning agent C may include deionized water, HF, NH₄OH, etc., but not limited thereto. In some implementations, the upper cleaning nozzle 130 may include a plurality of nozzles spaced apart from each other by a uniform gap.

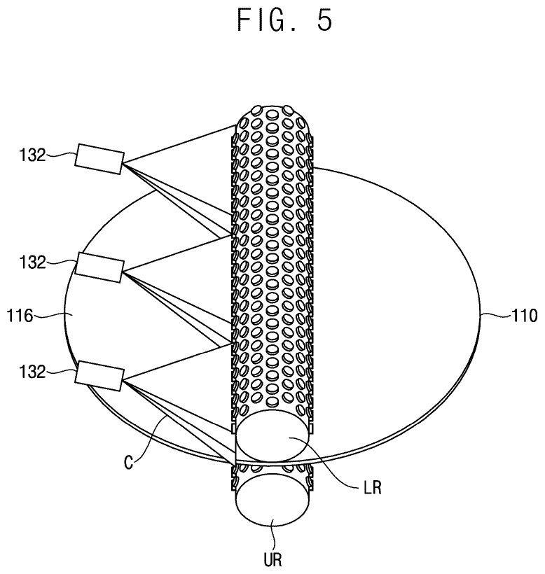

FIG. 4 is a perspective view illustrating an example of an operation of an upper cleaning nozzle of the apparatus in FIG. 1 according to some implementations. In FIG. 4, the upper cleaning nozzle2 130 may inject the cleaning agent C to a space between the upper brush UB and the upper surface 112 of the scrubbing jig 110. As described above, because the gap between the upper cleaning nozzles 130 may be uniform, the cleaning agent C may be uniformly supplied to the space between the upper brush UB and the upper surface 112 of the scrubbing jig 110.

In FIGS. 1 to 3, the lower cleaning nozzle 132 may be slantly arranged under the scrubbing jig 110. Further, the lower cleaning nozzle 132 may be positioned at one side of the lower brush LB. The lower cleaning nozzle 132 may selectively inject the cleaning agent C to the lower surface 116 of the scrubbing jig 110 and/or the lower brush LB. In some implementations, the lower cleaning nozzle 132 may include a plurality of nozzles spaced apart from each other by a uniform gap.

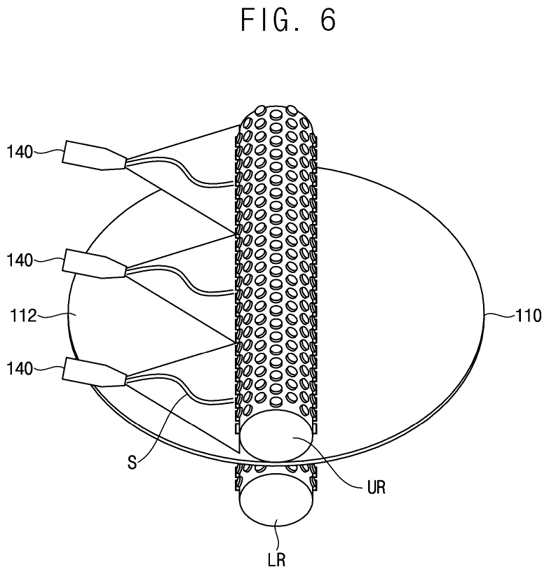

FIG. 5 is a perspective view illustrating an example of an operation of a lower cleaning nozzle of the apparatus in FIG. 1 according to some implementations. In FIG. 5, the lower cleaning nozzle2 132 may inject the cleaning agent C to a space between the lower brush LB and the lower surface 116 of the scrubbing jig 110. As described above, because the gap between the lower cleaning nozzles 132 may be uniform, the cleaning agent C may be uniformly supplied to the space between the lower brush LB and the lower surface 116 of the scrubbing jig 110.

In FIGS. 1 to 3, the upper ultrasonic wave nozzle 140 may be slantly arranged over the scrubbing jig 110. Further, the upper ultrasonic wave nozzle 140 may be positioned at one side of the upper brush UB. The upper ultrasonic wave nozzle 140 may selectively apply an ultrasonic wave S to the upper surface 112 of the scrubbing jig 110 and/or the upper brush UB. The ultrasonic wave S may vibrate the upper surface 112 of the scrubbing jig 110 and the upper brush UB to readily remove a contaminant from the upper surface 112 of the scrubbing jig 110 and the upper brush UB. In some implementations, the upper ultrasonic wave nozzle 140 may include a plurality of nozzles spaced apart from each other by a uniform gap.

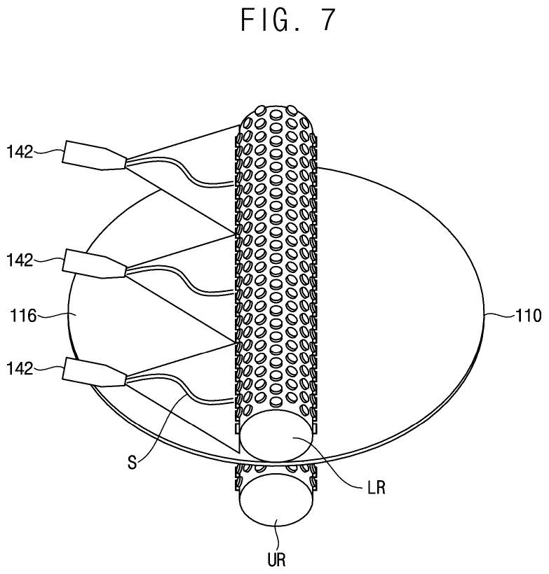

FIG. 6 is a perspective view illustrating an example of an operation of an upper ultrasonic wave nozzle of the apparatus in FIG. 1 according to some implementations. In FIG. 6, the upper ultrasonic wave nozzles 140 may apply the ultrasonic wave S to the upper brush UB and the upper surface 112 of the scrubbing jig 110. As described above, because the gap between the upper ultrasonic wave nozzles 140 may be uniform, the ultrasonic wave may be uniformly applied to the upper brush UB and the upper surface 112 of the scrubbing jig 110.

In FIGS. 1 to 3, the lower ultrasonic wave nozzle 142 may be slantly arranged under the scrubbing jig 110. Further, the lower ultrasonic wave nozzle 142 may be positioned at one side of the lower brush LB. The lower ultrasonic wave nozzle 142 may selectively apply the ultrasonic wave S to the lower surface 116 of the scrubbing jig 110 and/or the lower brush LB. The ultrasonic wave S may vibrate the lower surface 116 of the scrubbing jig 110 and the lower brush LB to readily remove a contaminant from the lower surface 116 of the scrubbing jig 110 and the lower brush LB. In some implementations, the lower ultrasonic wave nozzle 142 may include a plurality of nozzles spaced apart from each other by a uniform gap.

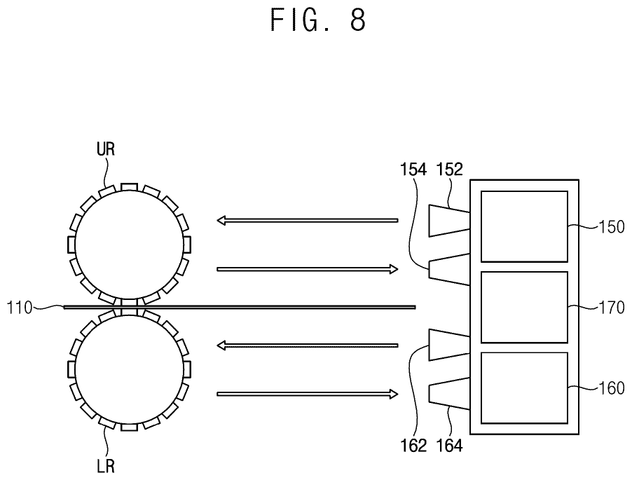

FIG. 7 is a perspective view illustrating an example of an operation of a lower ultrasonic wave nozzle of the apparatus in FIG. 1 according to some implementations. In FIG. 7, the lower ultrasonic wave nozzles 142 may apply the ultrasonic wave S to the lower brush LB and the lower surface 116 of the scrubbing jig 110. As described above, because the gap between the lower ultrasonic wave nozzles 142 may be uniform, the ultrasonic wave may be uniformly applied to the lower brush LB and the lower surface 116 of the scrubbing jig 110.

The upper imager 150 may photograph the upper brush UB to obtain an upper image. The upper imager 150 may include an upper light emitter 152 and an upper light receiver 154. The upper light emitter 152 may irradiate a light to the upper brush UB. The upper light receiver 154 may receive a light reflected from the upper brush UB.

The lower imager 160 may photograph the lower brush LB to obtain a lower image. The lower imager 160 may include a lower light emitter 162 and a lower light receiver 164. The lower light emitter 162 may irradiate a light to the lower brush LB. The lower light receiver 164 may receive a light reflected from the lower brush LB.

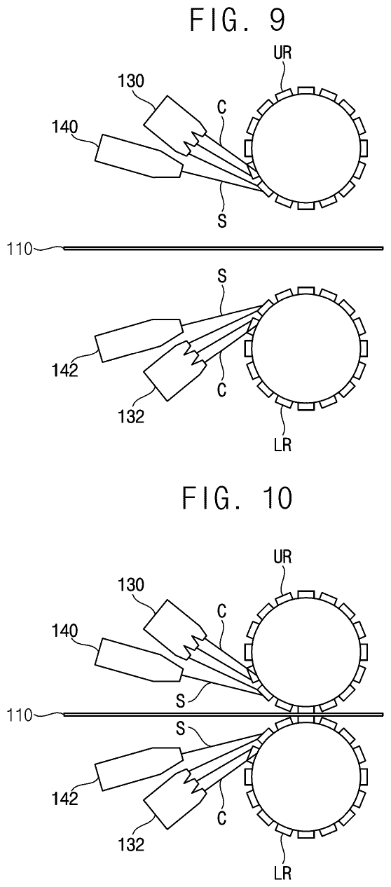

FIG. 8 is a perspective view illustrating an example of an operation of a controller of the apparatus in FIG. 1 according to some implementations. In FIG. 8, the controller 170 may receive the upper image obtained by the upper imager 150 and the lower image obtained by the lower imager 160. The controller 170 may detect (identify) contamination information of the upper brush UB based on the upper image. The controller 170 may detect (identify) contamination information of the lower brush LB based on the lower image. The controller 170 may control the scrubbing jig 110, the upper cleaning nozzle 130 and the upper ultrasonic wave nozzle 140 based on the contamination information of the upper brush UB. The controller 170 may control the scrubbing jig 110, the lower cleaning nozzle 132, the lower ultrasonic wave nozzle 142 based on the contamination information of the lower brush LB.

In some implementations, the operations of the controller 170 may be performed in the cleaning operation of the apparatus real time. That is, the upper imager 150 may obtain real time the upper image in the cleaning operation of the apparatus. The lower imager 160 may obtain real time the lower image in the cleaning operation of the apparatus. The controller 170 may receive real time the upper image and the lower image. The controller 170 may detect real time the contamination information of the upper brush UB and the lower brush LB from the upper image and the lower image. Accordingly, the operations of the scrubbing jig 110, the upper and the lower cleaning nozzles 130 and 132 and the upper and lower ultrasonic wave nozzles 140 and 142 may be optimized by the controller 170.

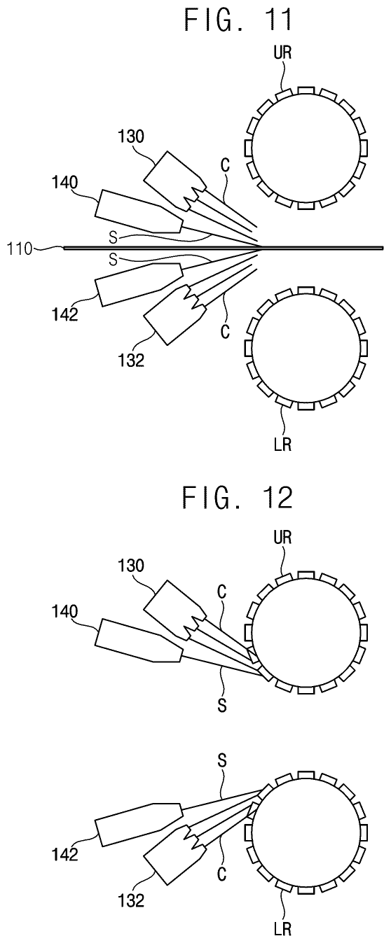

FIGS. 9 to 12 are views illustrating examples of operations of a cleaning nozzle and an ultrasonic wave nozzle of the apparatus in FIG. 1 according to some implementations. In FIG. 9, before an operation mode of the scrubbing jig 110, the upper brush UB may be spaced apart from the upper surface 112 of the scrubbing jig 110. The lower brush LB may also be spaced apart from the lower surface 116 of the scrubbing jig 110.

The upper cleaning nozzle 130 may inject the cleaning agent C to the upper brush UB. The upper ultrasonic wave nozzle 140 may apply the ultrasonic wave S to the upper brush UB. Thus, before the operation of the scrubbing jig 110, a part of the contaminants may be previously removed from the upper brush UB.

The lower cleaning nozzle 132 may inject the cleaning agent C to the lower brush LB. The lower ultrasonic wave nozzle 142 may apply the ultrasonic wave S to the lower brush LB. Thus, before the operation of the scrubbing jig 110, a part of the contaminants may be previously removed from the lower brush LB.

In FIG. 10, in the operation mode of the scrubbing jig 110, the upper brush UB may make contact with the upper surface 112 of the scrubbing jig 110. The lower brush LB may also make contact with the lower surface 116 of the scrubbing jig 110.

The upper cleaning nozzle 130 may inject the cleaning agent C to the space between the upper brush UB and the upper surface 112 of the scrubbing jig 110. The upper ultrasonic wave nozzle 140 may apply the ultrasonic wave S to the space between the upper brush UB and the upper surface 112 of the scrubbing jig 110. Accordingly, in the operation mode of the scrubbing jig 110, most of the contaminants may be removed from the upper brush UB.

The lower cleaning nozzle 132 may inject the cleaning agent C to the space between the lower brush LB and the lower surface 116 of the scrubbing jig 110. The lower ultrasonic wave nozzle 142 may apply the ultrasonic wave S to the space between the lower brush LB and the lower surface 116 of the scrubbing jig 110. Accordingly, in the operation mode of the scrubbing jig 110, most of the contaminants may be removed from the lower brush LB.

In FIG. 11, after the operation mode of the scrubbing jig 110, the upper brush UB may be upwardly moved from the upper surface 112 of the scrubbing jig 110. The lower brush LB may also be downwardly moved from the lower surface 116 of the scrubbing jig 110.

In the operation mode of the scrubbing jig 110, the upper surface 112 of the scrubbing jig 110 may be stained with the contaminant removed from the upper brush UB. The upper cleaning nozzle 130 may inject the cleaning agent C to the upper surface 112 of the scrubbing jig 110. The upper ultrasonic wave nozzle 140 may apply the ultrasonic wave S to the upper surface 112 of the scrubbing jig 110. Accordingly, the contaminant moved to the upper surface 112 of the scrubbing jig 110 from the upper brush UB may be removed.

Further, in the operation mode of the scrubbing jig 110, the lower surface 116 of the scrubbing jig 110 may be stained with the contaminant removed from the lower brush LB. Thus, the lower cleaning nozzle 132 may inject the cleaning agent C to the lower surface 116 of the scrubbing jig 110. The lower ultrasonic wave nozzle 142 may apply the ultrasonic wave S to the lower surface 116 of the scrubbing jig 110. Accordingly, the contaminant moved to the lower surface 116 of the scrubbing jig 110 from the lower brush LB may be removed.

In FIG. 12, when the scrubbing jig 110 may be moved from the space between the upper brush UB and the lower brush LB, the upper cleaning nozzle 130 may inject the cleaning agent C to the upper brush UB. The upper ultrasonic wave nozzle 140 may apply the ultrasonic wave S to the upper brush UB. Accordingly, the contaminant remaining on the upper brush UB may be finally removed. As a result, a contamination of a following wafer caused by the upper brush UB may be suppressed in a following process for cleaning the following wafer.

Further, the lower cleaning nozzle 132 may inject the cleaning agent C to the lower brush LB. The lower ultrasonic wave nozzle 142 may apply the ultrasonic wave S to the lower brush LB. Accordingly, the contaminant remaining on the lower brush LB may be finally removed. As a result, a contamination of the following wafer caused by the lower brush LB may be suppressed in the following process for cleaning the following wafer.

In some implementations, the apparatus may simultaneously clean one upper brush and one lower brush, but not limited thereto. Alternatively, the apparatus may simultaneously clean at least two upper brushes and at least two lower brushes.

According to some implementations, the at least two scrubbing surfaces of the scrubbing jig may simultaneously scrub the upper brush and the lower brush to reduce a time for cleaning the upper brush and the lower brush. Further, the cleaning nozzle may inject the cleaning agent to the brushes and the scrubbing jig and the ultrasonic wave nozzle may apply the ultrasonic wave to the brushes and the scrubbing jig to improve cleaning efficiency of the brushes. Furthermore, the controller may control the scrubbing jig, the cleaning nozzle and the ultrasonic nozzle based on the contamination information to optimally clean the brushes. As a result, a contamination of a wafer by contaminants in the brushes may be suppressed in a following cleaning process.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An apparatus for cleaning brushes, the apparatus comprising:
a scrubbing jig configured to simultaneously scrub at least two brushes that are configured to clean a wafer; and
wherein at least two scrubbing surfaces provided to the scrubbing jig are configured to contact the at least two brushes.

2. The apparatus of claim 1,
wherein the at least two brushes comprise an upper brush and a lower brush,
wherein the scrubbing jig is positioned between the upper brush and the lower brush, and
wherein the at least two scrubbing surfaces correspond to an upper surface and a lower surface of the scrubbing jig.

3. The apparatus of claim 2, wherein the scrubbing jig has a circular plate shape.

4. The apparatus of claim 3, wherein the scrubbing jig is configured to rotate with respect to a vertical axis.

5. The apparatus of claim 4, further comprising a plurality of guide rollers configured to rotatably support an edge portion of the scrubbing jig.

6. The apparatus of claim 1, wherein each of the at least two scrubbing surfaces comprises a plurality of scrubbing grooves.

7. The apparatus of claim 6, wherein the plurality of the scrubbing grooves extend radially from a center point of the scrubbing jig.

8. The apparatus of claim 1, further comprising at least one cleaning nozzle configured to inject a cleaning agent to the at least two brushes, the at least two scrubbing surfaces, or both of the at least two brushes and the at least two scrubbing surfaces.

9. The apparatus of claim 1, further comprising at least one ultrasonic wave nozzle configured to apply an ultrasonic wave to the at least two brushes, the at least two scrubbing surfaces, or both of the at least two brushes and the at least two scrubbing surfaces.

10. The apparatus of claim 1, further comprising:
an imager configured to obtain an image of the at least two brushes; and
a controller configured to identify contamination information of the at least two brushes based on the image and configured to control the scrubbing jig based on the contamination information.

11. An apparatus for cleaning brushes, the apparatus comprising:
a scrubbing jig rotatably arranged between an upper brush and a lower brush that are configured to clean a wafer, the scrubbing jig configured, with respect to a vertical axis, to simultaneously scrub the upper brush and the lower brush;
at least one upper cleaning nozzle configured to inject a cleaning agent to at least one of the upper brush or an upper surface of the scrubbing jig; and
at least one lower cleaning nozzle configured to inject the cleaning agent to at least one of the lower brushes or a lower surface of the scrubbing jig.

12. The apparatus of claim 11, wherein the scrubbing jig has a circular plate shape.

13. The apparatus of claim 11, wherein the scrubbing jig comprises:
a plurality of upper scrubbing grooves defined at the upper surface of the scrubbing jig; and
a plurality of lower scrubbing grooves defined at the lower surface of the scrubbing jig.

14. The apparatus of claim 13, wherein the plurality of the upper scrubbing grooves and the plurality of lower scrubbing grooves extend radially from a center point of the scrubbing jig.

15. The apparatus of claim 11, further comprising a plurality of guide rollers configured to rotatably support an edge portion of the scrubbing jig.

16. The apparatus of claim 11, further comprising:
at least one upper ultrasonic wave nozzle configured to apply an ultrasonic wave to at least one of the upper brush or the upper surface of the scrubbing jig; and
at least one lower ultrasonic wave nozzle configured to apply the ultrasonic wave to at least one of the lower brushes or the lower surface of the scrubbing jig.

17. The apparatus of claim 16, further comprising:
an imager configured to obtain images of the upper brush and the lower brush; and
a controller configured to identify contamination information of the upper brush and the lower brush based on the images and to control, based on the contamination information, the scrubbing jig, the upper cleaning nozzle and the lower cleaning nozzle, and the upper ultrasonic wave nozzle and the lower ultrasonic wave nozzle.

18. An apparatus for cleaning brushes, the apparatus comprising:
a scrubbing jig rotatably arranged between an upper brush and a lower brush that are configured to clean a wafer, the scrubbing jig configured, with respect to a vertical axis, to simultaneously scrub the upper brush and the lower brush;
at least one upper cleaning nozzle configured to inject a cleaning agent to at least one of the upper brushes or an upper surface of the scrubbing jig;
at least one lower cleaning nozzle configured to inject the cleaning agent to at least one of the lower brushes or a lower surface of the scrubbing jig;
at least one upper ultrasonic wave nozzle configured to apply an ultrasonic wave to at least one of the upper brushes or the upper surface of the scrubbing jig;
at least one lower ultrasonic wave nozzle configured to apply the ultrasonic wave to at least one of the lower brushes or the lower surface of the scrubbing jig;
an imager configured to obtain images of the upper brush and the lower brush; and
a controller configured to identify contamination information of the upper brush and the lower brush based on the images and to control, based on the communication information, the scrubbing jig, the upper cleaning nozzle and the lower cleaning nozzle, and the upper ultrasonic wave nozzle and the lower ultrasonic wave nozzle.

19. The apparatus of claim 18, wherein the scrubbing jig comprises:
a plurality of upper scrubbing grooves on the upper surface of the scrubbing jig extending in a radial direction from a center point of the scrubbing jig; and
a plurality of lower scrubbing grooves on the lower surface of the scrubbing jig extending in the radial direction from the center point of the scrubbing jig.

20. The apparatus of claim 18, further comprising a plurality of guide rollers configured to rotatably support an edge portion of the scrubbing jig.
